(19) United States
(12) Patent Application Publication
(10) Pub. No.: US 2017/0244026 A1
(43) Pub. Date: Aug. 24, 2017

(54) VARIABLE RESISTANCE MEMORY DEVICE AND METHOD OF MANUFACTURING THE SAME

(71) Applicant: SAMSUNG ELECTRONICS CO., LTD., SUWON-SI (KR)

(72) Inventors: ZHE WU, SUWON-SI (KR); DONG-HO AHN, HWASEONG-SI (KR); HIDEKI HORII, SEOUL (KR); JEONG-HEE PARK, HWASEONG-SI (KR)

(21) Appl. No.: 15/347,181

(22) Filed: Nov. 9, 2016

(30) Foreign Application Priority Data
Feb. 23, 2016 (KR) 10-2016-0021316

(51) Int. Cl. H01L 45/00; H01L 27/22; H01L 43/12; H01L 27/24; H01L 43/08

(52) U.S. Cl. CPC H01L 45/06; H01L 45/141; H01L 45/1253; H01L 45/126; H01L 27/2463; H01L 43/08; H01L 43/12; H01L 27/222; H01L 45/1616; H01L 45/1675

(57) ABSTRACT

A variable resistance memory device includes a first electrode layer and a selection device layer on the first electrode layer. The selection device layer includes a first chalcogenide material obtained by doping at least one of boron or carbon into a chalcogenide switching material. A second electrode layer is on the selection device layer. A variable resistance layer is on the second electrode layer. The variable resistance layer includes a second chalcogenide material including at least one different element from the chalcogenide switching material. A third electrode layer is on the variable resistance layer.

This application claims priority under 35 U.S.C. §119 to Korean Patent Application No. 10-2016-0021316, filed on Feb. 23, 2016, in the Korean Intellectual Property Office, the disclosure of which is incorporated by reference herein in its entirety.

### TECHNICAL FIELD

Exemplary embodiments of the present inventive concept relate to a variable resistance memory device, and more particularly to a method of manufacturing the same.

### DISCUSSION OF RELATED ART

A variable resistance memory device may include a selection device including a chalcogenide material. When a voltage is applied to the selection device including the chalcogenide material in a non-crystalline phase, an electronic structure of the selection device may be changed. Thus, the electrical properties of the selection device may also be changed from a non-conducting state to a conducting state. When the applied voltage is removed, the electrical properties of the selection device may be restored to the original non-conducting state.

### SUMMARY

Exemplary embodiments of the present inventive concept provide a variable resistance memory device including a selection device including a chalcogenide material into which at least one of boron (B) or carbon (C) is doped. Thus, a crystallization temperature of the selection device may increase, durability of the selection device may increase, and an off current passing through the selection device may be reduced.

Exemplary embodiments of the present inventive concept provide a method of manufacturing a variable resistance memory device having a selection device including a chalcogenide material into which at least one of boron or carbon is doped. Thus, a crystallization temperature of the selection device may increase, durability of the selection device may increase, and an off current passing through the selection device may be reduced.

According to an exemplary embodiment of the present inventive concept, a variable resistance memory device includes a first electrode layer and a selection device layer on the first electrode layer. The selection device layer includes a first chalcogenide material obtained by doping at least one of boron or carbon into a chalcogenide switching material. A second electrode layer is on the selection device layer. A variable resistance layer is on the second electrode layer. The variable resistance layer includes a second chalcogenide material including at least one different element from the chalcogenide switching material. A third electrode layer is on the variable resistance layer.

According to an exemplary embodiment of the present inventive concept, a variable resistance memory device includes a first electrode line layer extending in a first direction. The first electrode line layer includes a plurality of first electrode lines spaced apart from one another. A second electrode line layer is above the first electrode line layer. The second electrode line layer extends in a second direction that is different from the first direction. The second electrode line layer includes a plurality of second electrode lines spaced apart from one another. A third electrode line layer is above the second electrode line layer. The third electrode line layer includes a plurality of third electrode lines. A first memory cell layer is between the first electrode line layer and the second electrode line layer. The first memory cell layer includes a plurality of first memory cells arranged at intersections between the first electrode lines and the second electrode lines. A second memory cell layer is between the second electrode line layer and the third electrode line layer. The second memory cell layer includes a plurality of second memory cells arranged at intersections between the third electrode lines and the second electrode lines. Each of the plurality of first memory cells and each of the plurality of second memory cells includes a selection device layer, an electrode layer, and a variable resistance layer. The selection device layer includes a first chalcogenide material obtained by doping at least one of boron or carbon into a chalcogenide switching material. The variable resistance layer includes a second chalcogenide material having at least one element that is different from an element included in the chalcogenide switching material.

According to an exemplary embodiment of the present inventive concept, a variable resistance memory device includes a first electrode layer and a selection device layer on the first electrode layer. The selection device layer includes a first chalcogenide material obtained by doping at least one of boron or carbon into a chalcogenide switching material. The first chalcogenide material has a first melting point. A second electrode layer is on the selection device layer. A variable resistance layer is on the second electrode layer. The variable resistance layer includes a second chalcogenide material including at least one different element from the chalcogenide switching material. The second chalcogenide material has a second melting point lower than the first melting point. A third electrode layer is on the variable resistance layer.

According to an exemplary embodiment of the present inventive concept, a method of manufacturing a variable resistance memory device includes forming a first electrode layer and forming a selection device layer on the first electrode layer. The selection device layer including a first chalcogenide material obtained by doping at least one selected out of boron and carbon into a chalcogenide switching material. A second electrode layer is formed on the selection device layer. A variable resistance layer is formed on the second electrode layer. The variable resistance layer includes a second chalcogenide material including at least one different element from the chalcogenide switching material. A third electrode layer is formed on the variable resistance layer.

### BRIEF DESCRIPTION OF THE DRAWINGS

The above and other features of the inventive concept will become more apparent by describing in detail exemplary embodiments thereof, with reference to the accompanying drawing, in which:

FIG. 1 is an equivalent circuit diagram of a variable resistance memory device according to an exemplary embodiment of the present inventive concept t;

FIG. 2 is a perspective view of a variable resistance memory device according to an exemplary embodiment of the present inventive concept t;

FIG. 3 is a cross-sectional view taken along lines X-X′ and Y-Y′ of FIG. 2;

FIG. 4 is a graph of set and reset programming operations performed on a variable resistance layer of a variable resistance memory device according to an exemplary embodiment of the present inventive concept;

FIG. 5 is a schematic diagram of an ion diffusion path of a variable resistance layer when a voltage is applied to a memory cell, according to an exemplary embodiment of the present inventive concept;

FIG. 6 is a schematic graph showing a voltage-current (V-I) curve of a selection device layer, according to an exemplary embodiment of the present inventive concept;

FIGS. 7 to 10 are cross-sectional views of variable resistance memory devices according to exemplary embodiments of the present inventive concept, which correspond to the cross-sectional view of FIG. 3;

FIG. 11 is a perspective view of a variable resistance memory device according to an exemplary embodiment of the present inventive concept;

FIG. 12 is a cross-sectional view taken along lines 2X-2X′ and 2Y-2Y′ of FIG. 11;

FIG. 13 is a perspective view of a variable resistance memory device according to an exemplary embodiment of the present inventive concept;

FIG. 14 is a cross-sectional view taken along lines 3X-3X′ and 3Y-3Y′ of FIG. 13;

FIG. 15 is a perspective view of a variable resistance memory device according to an exemplary embodiment of the present inventive concept;

FIG. 16 is a cross-sectional taken along a line 4X-4X′ of FIG. 15;

FIGS. 17 to 19 are cross-sectional views, illustrating a method of manufacturing the variable resistance memory device of FIG. 2, according to an exemplary embodiment of the present inventive concept; and

FIG. 20 is a block diagram of a memory device according to an exemplary embodiment of the present inventive concept.

### DETAILED DESCRIPTION OF THE EMBODIMENTS

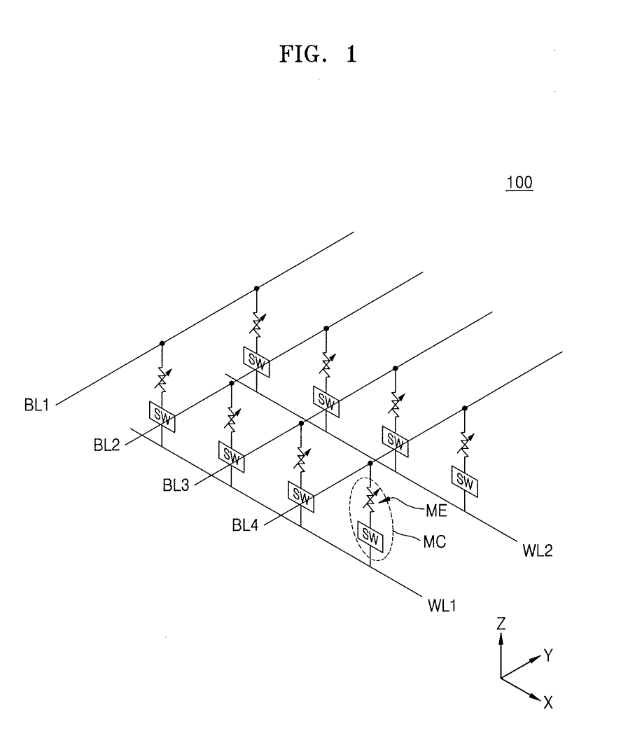

FIG. 1 is an equivalent circuit diagram of a variable resistance memory device according to an exemplary embodiment of the present inventive concept.

Referring to FIG. 1, a variable resistance memory device 100 may include word lines WL1 and WL2, which may extend in a first direction (e.g., an X direction) and may be spaced apart from each other in a second direction (e.g., a Y direction) that is perpendicular to the first direction. The variable resistance memory device 100 may include bit lines BL1, BL2, BL2, and BL4, which may be spaced apart from the word lines WL1 and WL2 in a third direction (e.g., a Z direction) and may extend in the second direction.

Memory cells MC may be respectively located between the bit lines BL1, BL2, BL3, and BL4 and the word lines WL1 and WL2. The memory cells MC may be located at intersections between the bit lines BL1, BL2, BL3, and BL4 and the word lines WL1 and WL2, and may each include a variable resistance layer ME configured to store information and a selection device layer SW configured to select a memory cell. The selection device layer SW may be referred to as a switching device layer or an access device layer.

The memory cells MC may each have substantially the same structures and may be arranged in the third direction. For example, in the memory cells MC located between the word line WL1 and the bit line BL1, the selection device layer SW may be electrically connected to the word line WL1, the variable resistance layer ME may be electrically connected to the bit line BL1, and the variable resistance layer ME and the selection device layer SW may be connected in series.

However, exemplary embodiments of the present inventive concept are not limited thereto. For example, positions of the selection device layer SW and the variable resistance layer ME may be exchanged in the memory cell MC. For example, in a memory cell MC, the variable resistance layer ME may be connected to the word line WL1, and the selection device layer SW may be connected to the bit line BL1.

A method of driving the variable resistance memory device 100 will be described below in more detail. A voltage may be applied to the variable resistance layer ME of the memory cell MC through the word lines WL1 and WL2 and the bit lines BL1, BL2, BL3, and BL4 so that current may flow into the variable resistance layer ME. For example, the variable resistance layer ME may include a phase-change material layer, which may be reversibly switched between a first state and a second state. However, exemplary embodiments of the present inventive concept are not limited thereto, and the variable resistance layer ME may include any variable resistor of which a resistance varies according to an applied voltage. For example, in a selected memory cell MC, a resistance of the variable resistance layer ME may be reversibly switched between the first state and the second state according to a voltage applied to the variable resistance layer ME.

Digital information, such as ‘0’ or ‘1’, may be stored in the memory cell MC depending on a variation in resistance of the variable resistance layer ME. Digital information may be erased from the memory cell MC. For example, a high-resistance state ‘0’ and a low-resistance state ‘1’ may be written as data in the memory cell MC. An operation of changing a high-resistance state ‘0’ into a low-resistance state ‘1’ may be referred to as a ‘set operation’, and an operation of changing a low-resistance state ‘1’ into a high-resistance state ‘0’ may be referred to as a ‘reset operation’. However, the memory cell MC according to exemplary embodiments of the present inventive concept is not limited to the above-described digital information (e.g., the high-resistance state ‘0’ and the low-resistance state ‘1’), and may store various other resistance states.

A desired memory cell MC may be addressed by selecting one of the word lines WL1 and WL2 and one of the bit lines BL1, BL2, BL3, and BL4. The memory cell MC may be programmed by applying a predetermined signal between the word lines WL1 and WL2 and the bit lines BL1, BL2, BL3, and BL4. Information (e.g., programmed information) corresponding to a resistance of the variable resistance layer ME of the memory cell MC may be read by measuring current passing through the bit lines BL1, BL2, BL3, and BL4.

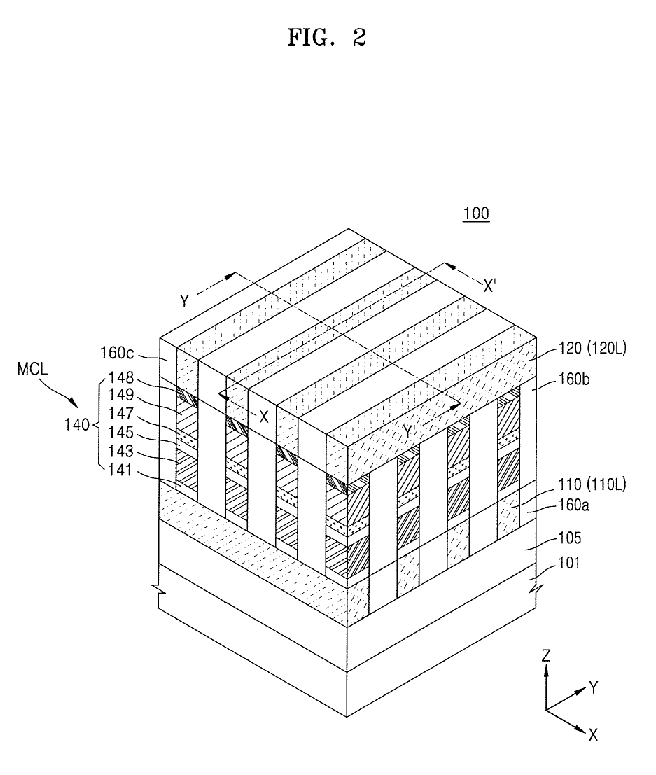

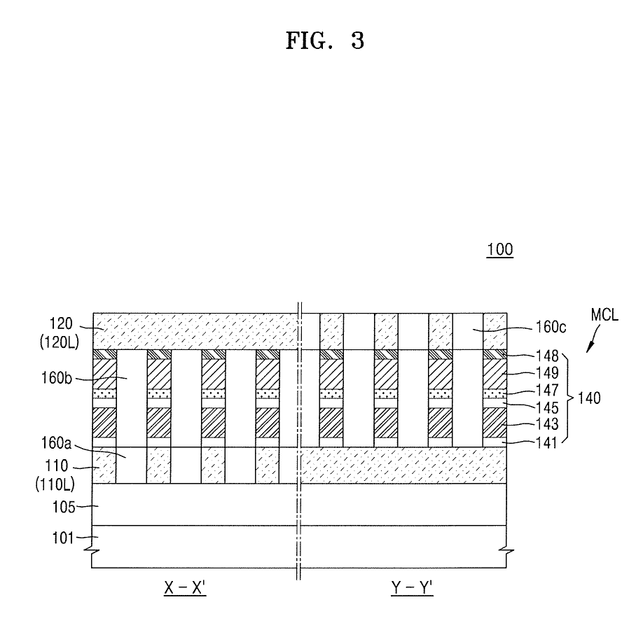

FIG. 2 is a perspective view of a variable resistance memory device according to an exemplary embodiment of the present inventive concept, and FIG. 3 is a cross-sectional view taken along lines X-X′ and Y-Y′ of FIG. 2.

Referring to FIGS. 2 and 3, the variable resistance memory device 100 may include a first electrode line layer 110L, a second electrode line layer 120L, and a memory cell layer MCL, which are disposed on a substrate 101.

An interlayer insulating layer 105 may be disposed on the substrate 101. The interlayer insulating layer 105 may include an oxide (e.g., silicon oxide) or a nitride (e.g., silicon nitride), and may electrically isolate the first electrode line layer 110L from the substrate 101. In the variable resistance memory device 100 according to an exemplary embodiment of the present inventive concept, the interlayer insulating layer 105 may be disposed on the substrate 101, but exemplary embodiments of the present inventive concept are not limited thereto. For example, in the variable resistance memory device 100 according to an exemplary embodiment of the present inventive concept, an IC layer may be disposed on the substrate 101, and memory cells may be disposed on the IC layer. The IC layer may include, for example, peripheral circuits for operations of the memory cells and/or a core circuit for calculations. For reference, a structure in which an IC layer including peripheral circuits and/or a core circuit is disposed on a substrate and memory cells are disposed on the IC layer may be referred to as a Cell On Peri (COP) structure.

The first electrode line layer 110L may include a plurality of first electrode lines 110, which may extend parallel to one another in a first direction (e.g., the X direction). The second electrode line layer 120L may include a plurality of second electrode lines 120, which may extend parallel to one another in a second direction (e.g., the Y direction) that may intersect the first direction. The first direction may cross the second direction at right angles.

Operations of the variable resistance memory device 100 will be described in more detail below. The first electrode lines 110 may be word lines (see, e.g., the word lines WL illustrated in FIG. 1), and the second electrode lines 120 may be bit lines (see, e.g., the bit lines BL illustrated in FIG. 1). Alternatively, the first electrode lines 110 may be bit lines, and the second electrode lines 120 may be word lines.

Each of the first electrode lines 110 and the second electrode lines 120 may include a metal, a conductive metal nitride, a conductive metal oxide, or a combination thereof. Each of the first electrode lines 110 and the second electrode lines 120 may include tungsten (W), tungsten nitride (WN), gold (Au), silver (Ag), copper (Cu), aluminum (Al), titanium aluminum nitride (TiAlN), iridium (Ir), platinum (Pt), palladium (Pd), ruthenium (Ru), zirconium (Zr), rhodium (Rh), nickel (Ni), cobalt (Co), chromium (Cr), tin (Sn), zinc (Zn), indium tin oxide (ITO), an alloy thereof, or a combination thereof. Each of the first electrode lines 110 and the second electrode lines 120 may include a metal layer and a conductive barrier layer covering at least a portion of the metal layer. The conductive barrier layer may include, for example, titanium (Ti), titanium nitride (TiN), tantalum (Ta), tantalum nitride (TaN), or a combination thereof.

The memory cell layer MCL may include a plurality of memory cells 140 (see, e.g., memory cells MC illustrated in FIG. 1), which may be spaced apart from one another in a first direction and a second direction. The first electrode lines 110 may intersect the second electrode lines 120. The memory cells 140 may be positioned between the first electrode line layer 110L and the second electrode line layer 120L at intersections between the first electrode lines 110 and the second electrode lines 120.

The memory cells 140 may have square pillar structures. However, exemplary embodiments of the present inventive concept are not limited thereto, and the memory cells 140 are not limited to the square pillar structures. For example, the memory cells 140 may have various other pillar structures, such as cylindrical structures, elliptical pillar structures, or polygonal pillar structures. The memory cells 140 may have lower portions wider than upper portions or have upper portions wider than lower portions. For example, when the memory cells 140 are formed by using an etching process, the memory cells 140 may have lower portions wider than upper portions. When the memory cells 140 are formed by using a damascene process, the memory cells 140 may have upper portions wider than lower portions. In the etching process or the damascene process, material layers may be etched by precisely controlling an etching operation so that side surfaces of the memory cells 140 are substantially vertical and upper portions of the memory cells 140 are almost as wide as lower portions of the memory cells 140. FIGS. 2 and 3 illustrate a case in which the side surfaces of the memory cells 140 are substantially vertical and exemplary embodiments of the present inventive concept in which the side surfaces of the memory cells 140 are substantially vertical are described in more detail below. However, exemplary embodiments of the present inventive concept are not limited thereto, and the memory cells 140 may have lower portions wider than upper portions or have upper portions wider than lower portions.

Each of the memory cells 140 may include a lower electrode layer 141, a selection device layer 143, a middle electrode layer 145, a heating electrode layer 147, a variable resistance layer 149, and an upper electrode layer 148. The lower electrode layer 141 may be referred to as a first electrode layer, the middle electrode layer 145 and the heating electrode layer 147 may be referred to as second electrode layers, and the upper electrode layer 148 may be referred to as a third electrode layer.

In some exemplary embodiments of the present inventive concept, the variable resistance layer 149 (see, e.g., the variable resistance layer ME illustrated in FIG. 1) may include a phase-change material, which may be reversibly switched between an amorphous state and a crystalline state according to a heating time. For example, a phase of the variable resistance layer 149 may be reversibly changed due to Joule heat generated due to a voltage applied to both ends of the variable resistance layer 149, and the variable resistance layer 149 may include a phase-change material of which a resistance may vary according to the phase change. For example, the phase-change material may be put into a high-resistance state in an amorphous phase, and put into a low-resistance state in a crystalline phase. By defining the high-resistance state as ‘0’ and defining the low-resistance state as ‘1’, data may be stored in the variable resistance layer 149.

In some exemplary embodiments of the present inventive concept, the variable resistance layer 149 may include a chalcogenide material serving as a phase-change material. For example, the variable resistance layer 149 may include germanium-antimony-tellurium (Ge—Sb—Te, abbreviated to GST). As used herein, hyphenated (−) chemical compositions may denote elements included in specific mixtures or compounds and may refer to all chemical formulas including the denoted elements. For example, GST may refer to materials, such as Ge₂Sb₂Te₅, Ge₂Sb₂Te₇, Ge₁Sb₂Te₄, or Ge₁Sb₄Te₇.

In addition to Ge—Sb—Te (GST), the variable resistance layer 149 may include various other chalcogenide materials. For example, the variable resistance layer 149 may include a chalcogenide material, which is at least two selected from silicon (Si), germanium (Ge), antimony (Sb), tellurium (Te), bismuth (Bi), indium (In), tin (Sn), and selenium (Se) or a combination thereof.

Each element included in the variable resistance layer 149 may have various stoichiometric compositions. A crystallization temperature and melting point of the variable resistance layer 149, a phase change rate of the variable resistance layer 149 relative to crystallization energy, and data retention of the variable resistance layer 149 may be controlled according to a stoichiometric composition of each element. In an exemplary embodiment of the present inventive concept, a melting point of a chalcogenide material included in the variable resistance layer 149 may range from about 500° C. to about 800° C.

The variable resistance layer 149 may include impurities, such as at least one of boron (B), carbon (C), nitrogen (N), oxygen (O), phosphorus (P), or sulfur (S). A driving current of the variable resistance memory device 100 may vary due to the impurities. The variable resistance layer 149 may include a metal. For example, the variable resistance layer 149 may include at least one of aluminum (Al), gallium (Ga), zinc (Zn), titanium (Ti), chromium (Cr), manganese (Mn), iron (Fe), cobalt (Co), nickel (Ni), molybdenum (Mo), ruthenium (Ru), palladium (Pd), hafnium (Hf), tantalum (Ta), iridium (Ir), platinum (Pt), zirconium (Zr), thallium (Tl), palladium (Pd), or polonium (Po). The above-described metals may increase electrical conductivity and thermal conductivity of the variable resistance layer 149, thus increasing a crystallization rate and a set rate. The above-described metals may increase data retention of the variable resistance layer 149.

The variable resistance layer 149 may have a multi-layered structure formed by stacking at least two layers having different physical properties. The number and thicknesses of a plurality of layers included in the variable resistance layer 149 may be selected, as desired. A barrier layer may be formed between the plurality of layers. The barrier layer may reduce or prevent a diffusion of materials between the plurality of layers. The barrier layer may reduce diffusion of a preceding layer during formation of a subsequent layer from among the plurality of layers.

The variable resistance layer 149 may have a super-lattice structure formed by alternately stacking a plurality of layers including different materials. For example, the variable resistance layer 149 may include a structure formed by alternately stacking a first layer including germanium-tellurium (Ge—Te) and a second layer including antimony-tellurium (Sb—Te). However, materials included in the first layer and the second layers are not limited to Ge—Te and Sb—Te but may include various materials, as desired, such as one or more of the materials described above.

According to an exemplary embodiment of the present inventive concept, the variable resistance layer 149 may include a phase-change material, however, exemplary embodiments of the present inventive concept are not limited thereto. The variable resistance layer 149 included in the variable resistance memory device 100 may include various materials having resistance variation characteristics.

In some exemplary embodiments of the present inventive concept, when the variable resistance layer 149 includes a transition metal oxide, the variable resistance memory device 100 may be a resistive RAM (ReRAM). At least one electrical path may be generated or annihilated in the variable resistance layer 149 including the transition metal oxide due to a program operation. When the electrical path is generated, the variable resistance layer 149 may have a low resistance value. When the electrical path is annihilated, the variable resistance layer 149 may have a high resistance value. The variable resistance memory device 100 may store data by using a resistance difference of the variable resistance layer 149.

When the variable resistance layer 149 includes a transition metal oxide, the transition metal oxide may include at least one metal, such as Ta, Zr, Ti, Hf, Mn, Y, Ni, Co, Zn, Nb, Cu, Fe, or Cr. For example, the transition metal oxide may include a single layer or a multi-layered structure including at least one of Ta₂O₅₋ₓ ZrO₂₋ₓ, TiO₂₋ₓ, HfO₂₋ₓ, MnO₂₋ₓ, Y₂O₃₋ₓ, NiO_{1-y}, Nb₂O₅₋ₓ, CuO_{1-y}, or Fe₂O₃₋ₓ In the above-described materials, x may be selected in the range of 0≦x≦1.5, and y may be selected in the range of but exemplary embodiments of the present inventive concept are not limited thereto.

In some exemplary embodiments of the present inventive concept, when the variable resistance layer 149 has a magnetic tunnel junction (MTJ) structure including two electrodes including a magnetic material and a dielectric material disposed between the two electrodes, the variable resistance memory device 100 may be a magnetic RAM (MRAM).

The two electrodes may be a pinned magnetic layer and a free magnetic layer, and the dielectric material disposed between the two electrodes may be a tunnel barrier layer. The pinned magnetic layer may have a pinned magnetization direction, while the free magnetic layer may have a variable magnetization direction, which may be parallel to or anti-parallel to the magnetization direction of the pinned magnetic layer. The magnetization directions of the pinned magnetic layer and the free magnetic layer may be parallel to one surface of the tunnel barrier layer, but exemplary embodiments of the present inventive concept are not limited thereto. The magnetization directions of the pinned magnetic layer and the free magnetic layer may be perpendicular to one surface of the tunnel barrier layer.

When the magnetization direction of the free magnetic layer is parallel to the magnetization direction of the pinned magnetic layer, the variable resistance layer 149 may have a first resistance value. When the magnetization direction of the free magnetic layer is anti-parallel to the magnetization direction of the pinned magnetic layer, the variable resistance layer 149 may have a second resistance value. The variable resistance memory device 100 may store data by using a difference between the first and second resistance values. The magnetization direction of the free magnetic layer may vary due to spin torque of electrons in a program current.

Each of the pinned magnetic layer and the free magnetic layer may include a magnetic material. The pinned magnetic layer may include an anti-ferromagnetic material capable of pinning a magnetization direction of a ferromagnetic material included in the pinned magnetic layer. The tunnel barrier layer may include any one oxide, such as, magnesium (Mg), titanium (Ti), aluminum (Al), magnesium zinc (MgZn), or magnesium boron (MgB), but exemplary embodiments of the present inventive concept are not limited thereto.

The selection device layer 143 (see, e.g., the selection device layer SW illustrated in FIG. 1) may be a current adjusting layer capable of adjusting the flow of current. The selection device layer 143 may include a material layer of which a resistance may vary according to a magnitude of a voltage applied to both ends of the selection device layer 143. For example, the selection device layer 143 may include an ovonic threshold switching (OTS) material. Functions of the selection device layer including the OTS material will be described in more detail below. When a voltage lower than a threshold voltage Vt is applied to the selection device layer 143, the selection device layer 143 may maintain a high-resistance state in which current hardly flows. When a voltage higher than the threshold voltage Vt is applied to the selection device layer 143, the selection device layer 143 may be put into a low-resistance state so that current may start to flow. When current flowing through the selection device layer 143 is smaller than a holding current, the selection device layer 143 may change into a high-resistance state.

The selection device layer 143 may include a chalcogenide switching material, which is an OTS material. In an exemplary embodiment of the present inventive concept, the chalcogenide switching material may include arsenic (As) and may further include at least two of silicon (Si), germanium (Ge), antimony (Sb), tellurium (Te), selenium (Se), indium (In), or tin (Sn). The chalcogenide switching material may include selenium (Se) and may further include at least two of silicon (Si), germanium (Ge), antimony (Sb), tellurium (Te), arsenic (As), indium (In), or tin (Sn).

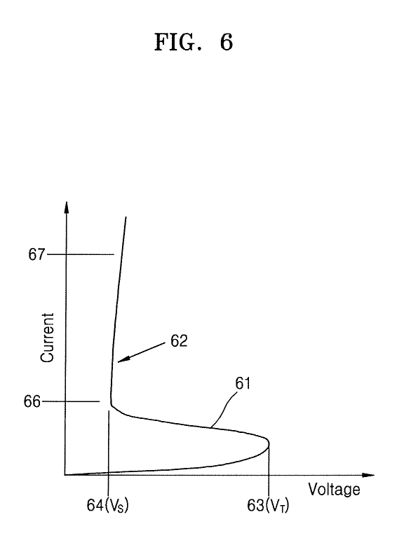

In general, chalcogen elements may be characterized by divalent bonding and the presence of lone pair electrons. The divalent bonding of chalcogen elements may lead to formation of chain and ring structures to form a chalcogenide material, and the lone pair electrons may provide an electron source for forming conductive filaments. For example, triatomic and tetratomic modifiers, for example, aluminum (Al), gallium (Ga), indium (In), germanium (Ge), tin (Sn), silicon (Si), phosphorus (P), arsenic (As), and antimony (Sb), may be included in the chain and ring structures of the chalcogen elements and determine structural rigidity of the chalcogenide material. The chalcogenide material may be categorized as either a switching material or a phase-change material depending on crystallinity or other structural redistribution capability. The selection device layer 143 will be described in more detail below with reference to FIG. 6.

The heating electrode layer 147 may be positioned between the middle electrode layer 145 and the variable resistance layer 149 and may contact the variable resistance layer 149. The heating electrode layer 147 may heat the variable resistance layer 149 during a set operation or a reset operation. The heating electrode layer 147 may include a conductive material capable of generating sufficient heat to change phase of the variable resistance layer 149. The heating electrode layer 147 may include a carbon-based conductive material. In some exemplary embodiments of the present inventive concept, the heating electrode layer 147 may include metals having high melting points or nitrides thereof, such as TiN, TiSiN, TiAlN, TaSiN, TaAlN, TaN, WSi, WN, TiW, MoN, NbN, TiBN, ZrSiN, WSiN, WBN, ZrAlN, MoAlN, TiAl, TiON, TiAlON, WON, TaON, carbon (C), silicon carbide (SiC), silcon carbonitride (SiCN), carbon nitride (CN), titanium carbon nitride (TiCN), tantalum carbon nitride (TaCN), or a combination thereof. A material included in the heating electrode layer 147 is not limited to the above-described materials.

The lower electrode layer 141, the middle electrode layer 145, and the upper electrode layer 148 may be a current path and may include a conductive material. For example, each of the lower electrode layer 141, the middle electrode layer 145, and the upper electrode layer 148 may include a metal, a conductive metal nitride, a conductive metal oxide, or a combination thereof. For example, each of the lower electrode layer 141, the middle electrode layer 145, and the upper electrode layer 148 may include at least one of carbon (C), titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tungsten (W), or tungsten nitride (WN), but exemplary embodiments of the present inventive concept are not limited thereto.

The lower electrode layer 141 and the upper electrode layer 148 may be selectively formed. For example, the lower electrode layer 141 and the upper electrode layer 148 may be omitted. The lower electrode layer 141 and the upper electrode layer 148 may be positioned between the first and second electrode lines 110 and 120 and the selection device layer 143 and the variable resistance layer 149, which may prevent generation of contamination or contact failures due to a direct contact of the selection device layer 143 and the variable resistance layer 149 with the first and second electrode lines 110 and 120.

The middle electrode layer 145 may reduce or prevent transmission of heat from the heat electrode layer 147 to the selection device layer 143. The selection device layer 143 may include a chalcogenide switching material that is in an amorphous state. However, with the downscaling of the variable resistance memory device 100, thicknesses and widths of the variable resistance layer 149, the selection device layer 143, the heating electrode layer 147, and the middle electrode layer 145 and distances therebetween may be reduced. Thus, during an operation of the variable resistance memory device 100, when a phase of the variable resistance layer 149 is changed due to heat generated by the heating electrode layer 147, the selection device layer 143 located adjacent to the heating electrode layer 147 may be affected by the generated heat. For example, the selection device layer 143 may be partially crystallized by heat generated by the heating electrode layer 147 adjacent to the selection device layer 143. Thus, the selection device layer 143 may be degraded and damaged.

In the variable resistance memory device 100 according to an exemplary embodiment of the present inventive concept, the middle electrode layer 145 may be relatively thick, and thus heat generated by the heating electrode layer 147 need not be transmitted to the selection device layer 143. FIGS. 2 and 3 illustrate an example in which the middle electrode layer 145 has a similar thickness to a thickness of the lower electrode layer 141 or the upper electrode layer 148. However, the middle electrode layer 145 may be formed to a greater thickness than the lower electrode layer 141 or the upper electrode layer 148, which may reduce or prevent transmission of heat. For example, the middle electrode layer 145 may have a thickness of about 10 nm to about 100 nm, but exemplary embodiments of the present inventive concept are not limited thereto. The middle electrode layer 145 may include at least one thermal barrier layer, which may reduce or prevent a transmission of heat. When the middle electrode layer 145 includes at least two thermal barrier layers, the middle electrode layer 145 may have a structure formed by alternately stacking thermal barrier layers and electrode material layers.

A first insulating layer 160a may be positioned between the first electrode lines 110, while a second insulating layer 160b may be positioned between the memory cells 140 of the memory cell layer MCL. A third insulating layer 160c may be positioned between the second electrode lines 120. The first to third insulating layers 160a to 160c may include the same material. Alternatively, at least one of the first to third insulating layers 160a to 160c may include a different material from the remaining insulating layers. The first to third insulating layers 160a to 160c may include, for example, a dielectric material, such as an oxide or a nitride, which may electrically isolate devices of each layer from one another. Air gaps may be formed instead of the second insulating layer 160b. When the air gaps are formed, an insulating liner having a predetermined thickness may be formed between the air gaps and the memory cells 140.

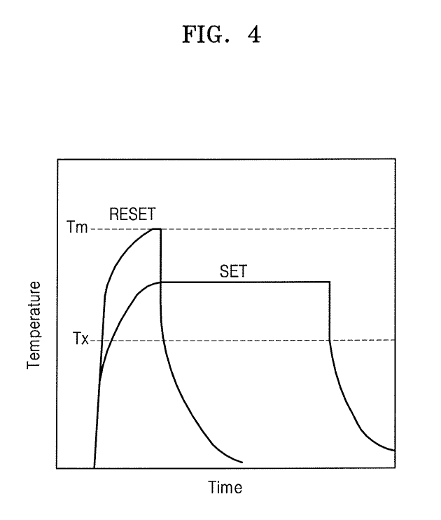

FIG. 4 is a graph of set and reset programming operations performed on a variable resistance layer of a variable resistance memory device according to an exemplary embodiment of the present inventive concept.

Referring to FIG. 4, a phase-change material included in a variable resistance layer (see, e.g., variable resistance layer 149 illustrated in FIG. 3) may be heated for a predetermined time at a temperature between a crystallization temperature Tx and a melting point Tm and slowly cooled. The phase-change material may be in a crystalline state. The crystalline state may be referred to as a ‘set state’ in which data ‘0’ is stored. In contrast, when the phase-change material is heated to a temperature equal to or higher than the melting point Tm and rapidly cooled, the phase-change material may be in an amorphous state. The amorphous state may be referred to as a ‘reset state’ in which data ‘1’ is stored. These phase-change characteristics of the phase-change material may be substantially the same as the phase-change characteristics described in more detail above.

Thus, data may be stored by supplying current to the variable resistance layer 149, and data may be read by measuring a resistance value of the variable resistance layer 149. A heating temperature of the phase-change material may be proportional to the amount of current, and as the amount of current increases, obtaining a high integration density may become more difficult. Since transition to an amorphous state may occur as a result of a larger current than transition to a crystalline state, power consumption of the variable resistance memory device may increase. Thus, a phase-change material may be changed to a crystalline state or an amorphous state by heating the phase-change material with a relatively small current, which may reduce power consumption. For example, a current (e.g., a reset current) for transition to an amorphous state may be reduced, and thus high integration density may be created.

Various materials reducing a reset current may be included in the variable resistance layer 149. In an exemplary embodiment of the present inventive concept, a chalcogenide material including at least two of silicon (Si), germanium (Ge), antimony (Sb), tellurium (Te), bismuth (Bi), indium (In), tin (Sn), or selenium (Se) may be used as a phase-change material included in the variable resistance layer 149. A chalcogenide material including impurities, such as, at least one of boron (B), carbon (C), nitrogen (N), oxygen (O), phosphorus (P), or sulfur (S) may be used as a phase-change material included in the variable resistance layer 149.

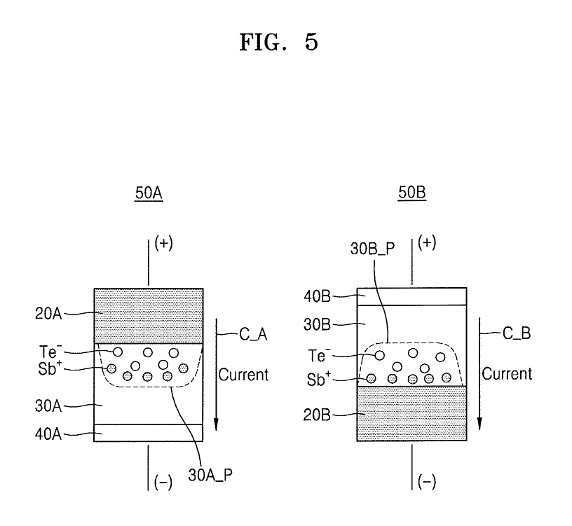

FIG. 5 is a schematic diagram of an ion diffusion path of a variable resistance layer when a voltage is applied to a memory cell, according to an exemplary embodiment of the present inventive concept.

Referring to FIG. 5, a first memory cell 50A may include a first electrode 20A, a variable resistance layer 30A, and a second electrode 40A, which are sequentially stacked. The first electrode 20A may include a conductive material capable of generating sufficient heat to change a phase of the variable resistance layer 30A. The first electrode 20A may correspond to the heating electrode layer 147 described with reference to FIGS. 2 and 3. In the first memory cell 50A, a positive voltage may be applied to the first electrode 20A, and a negative voltage may be applied to the second electrode 40A. Thus, as indicated by a first arrow C_A, current may flow from the first electrode 20A through the variable resistance layer 30A to the second electrode 40A.

Heat may be generated in the first electrode 20A due to current flowing through the first electrode 20A. Thus, a phase of a portion 30A_P of the variable resistance layer 30A adjacent to an interface between the first electrode 20A and the variable resistance layer 30A may be changed. For example, during a ‘reset operation’ in which the portion 30A_P of the variable resistance layer 30A is changed from a crystalline state (e.g., a low-resistance state) to an amorphous state (e.g., a high-resistance state), positive ions and negative ions in the portion 30A_P may diffuse at respectively different rates due to an applied voltage. For example, in the portion 30A_P of the variable resistance layer 30A, a diffusion rate of positive ions (e.g., antimony ions (Sb+)) may be higher than a diffusion rate of negative ions (e.g., tellurium ions (Te−)). Thus, the antimony ions (Sb+) may diffuse in a larger amount than the tellurium ions (Te) toward the second electrode 40A to which a negative voltage is applied. A rate at which the antimony ions (Sb+) diffuse toward the second electrode 40A may be higher than a rate at which the tellurium ions (Te−) diffuse toward the first electrode 20A.

A second memory cell 50B may include a first electrode 20B, a variable resistance layer 30B, and a second electrode 40B. A negative voltage may be applied to the first electrode 20B, and a positive voltage may be applied to the second electrode 40B so that current may flow from the second electrode 40B through the variable resistance layer 30B to the first electrode 20B as indicated by a second arrow C_B.

Heat may be generated in the first electrode 20B due to current flowing through the first electrode 20B. Thus, a phase of a portion 30B_P of the variable resistance layer 30B adjacent to an interface between the first electrode 20B and the variable resistance layer 30B may be changed. A diffusion rate of antimony ions (Sb+) may be higher than a diffusion rate of tellurium ions (Te−) in the portion 30B_P of the variable resistance layer 30B. The antimony ions (Sb+) may diffuse in a larger amount than the tellurium ions (Te−) toward the first electrode 20B to which a negative voltage is applied.

Thus, in the second memory cell 50B, the concentration of antimony ions (Sb+) may be higher near an interface between the first electrode 20B and the variable resistance layer 30B than in other regions, thus causing a partial variation in the concentration of the variable resistance layer 30B. In the first memory cell 50A, the concentration of tellurium ions (Te−) may be higher near an interface between the first electrode 20A and the variable resistance layer 30A than in other regions, thus causing a partial variation in the concentration of the variable resistance layer 30A.

Thus, the distributions of ions or vacancies in the variable resistance layers 30A and 30B may vary according to magnitudes of voltages applied to the variable resistance layers 30A and 30B, directions of currents flowing through the variable resistance layers 30A and 30B, and geometries of the variable resistance layers 30A and 30B and the first electrodes 20A and 20B. Due to the partial variations in the concentrations of the variable resistance layers 30A and 30B, even if the same voltage is applied, resistances of the variable resistance layers 30A and 30B may vary. Thus, the first and second memory cells 50A and 50B may exhibit different operating characteristics, for example, different resistances.

In FIG. 5, antimony ions (Sb+) and tellurium ions (Te−) are described as examples to describe ion diffusion paths, but exemplary embodiments of the present inventive concept are not limited thereto. For example, the variable resistance layers 30A and 30B may include a chalcogenide material, which includes at least two of silicon (Si), germanium (Ge), antimony (Sb), tellurium (Te), bismuth (Bi), indium (In), tin (Sn), or selenium (Se) or a combination thereof. The variable resistance layers 30A and 30B may include impurities, such as, at least one of boron (B), carbon (C), nitrogen (N), oxygen (O), phosphorus (P), or sulfur (S). Thus, diffusion extents of ions in the variable resistance layers 30A and 30B may vary according to kinds and compositions of materials included in the variable resistance layers 30A and 30B and kinds and concentrations of impurities. As a result, variations in operating characteristics of the first and second memory cells 50A and 50B may further increase.

Since the variable resistance memory device 100 according to an exemplary embodiment of the present inventive concept includes a selection device layer 143 including a chalcogenide switching material, a process for forming a transistor or a diode might not be performed. For example, after a diode is formed, a high-temperature annealing process for activating impurities contained in the diode may be performed. However, the variable resistance layer 149 including a phase-change material may be damaged or contaminated in the high-temperature annealing environment. However, forming the variable resistance memory device 100 according to an exemplary embodiment of the present inventive concept need not include processes for forming a transistor or a diode. Thus, damage or contamination of the variable resistance layer 149, which may occur during the processes for forming a transistor or a diode, may be reduced or prevented. Thus, the variable resistance memory device 100 according to an exemplary embodiment of the present inventive concept may increase reliability of semiconductor devices including the variable resistance memory device 100.

In general, when a transistor or a diode is formed, the transistor or the diode may be formed in a substrate. A variable resistance memory device may be formed by stacking a plurality of layers in a vertical direction. For example, the variable resistance layer 149 may be damaged or contaminated due to a high-temperature annealing process for activating the diode. Thus, errors may occur in forming a cross-point stack structure in which the diode is positioned on the variable resistance layer 149. However, the variable resistance memory device 100 according to an exemplary embodiment of the present inventive concept may use the selection device layer 143 including a chalcogenide switching material instead of the diode, and thus a three-dimensional (3D) cross-point stack structure in which a plurality of layers are stacked in a vertical direction may be formed with increased reliability and yield. Thus, integration density of the variable resistance memory device 100 may be increased.

FIG. 6 is a schematic graph showing a voltage-current (V-I) curve of a selection device layer, according to an exemplary embodiment of the present inventive concept.

Referring to FIG. 6, a first curve 61 shows a V-I relationship in a state in which no current flows through a selection device layer (see, e.g., selection device layer 143 illustrated in FIG. 3). The selection device layer 143 may act as a switching device having a threshold voltage Vt having a first voltage level 63. When a voltage slowly increases at a voltage of 0 and a current of 0, current may hardly flow through the selection device layer 143 until the voltage reaches a threshold voltage Vt (e.g., the first voltage level 63). However, when the voltage exceeds the threshold voltage Vt, current flowing through the selection device layer 143 may sharply increase, and a voltage applied to the selection device layer 143 may be dropped to a saturation voltage Vs (e.g., a second voltage level 64).

A second curve 62 shows a V-I relationship in a state in which current flows through the selection device layer 143. As current flowing through the selection device layer 143 becomes higher than a first current level 66, a voltage applied to the selection device layer 143 may be slightly higher than the second voltage level 64. For example, while the current flowing through the selection device layer 143 is increasing from the first current level 66 to the second current level 67, the voltage applied to the selection device layer 143 may slightly increase from the second voltage level 64. That is, once current flows through the selection device layer 143, the voltage applied to the selection device layer 143 may be substantially maintained at the saturation voltage Vs. If current is reduced to a holding current level (e.g., the first current level 66) or less, the selection device layer 143 may be switched again to a resistance state. Thus, current may be substantially blocked until the voltage increases to the threshold voltage Vt.

The selection device layer 143 may include a chalcogenide switching material. When the selection device layer 143 includes an undoped chalcogenide switching material, a crystallization temperature of the undoped chalcogenide switching material may be too low to be applied to a process of manufacturing a memory device. Thus, errors may occur in manufacturing a 3D cross-point stack structure. Additionally, a relatively small number of memory devices may be operated at one time due to a large off current passing through the chalcogenide switching material. Reliability of a variable resistance memory device may be reduced due to relatively low durability of the chalcogenide switching material. Thus, a crystallization temperature and durability of the chalcogenide switching material may be increased and the off current passing through the chalcogenide switching material may be reduced so that the selection device layer 143 using the chalcogenide switching material may be used for a 3D cross-point stack structure instead of a diode.

According to an exemplary embodiment of the present inventive concept, light elements may be doped into the chalcogenide switching material. In an exemplary embodiment of the present inventive concept, when boron and/or carbon is doped into the chalcogenide switching material, a carrier hopping site included in the chalcogenide switching material may be reduced. Thus, resistivity of the selection device layer 143 including the chalcogenide switching material into which boron and/or carbon is doped may increase, and an off current passing through the selection device layer 143 may be reduced. Density of the selection device layer 143 may increase, and migration of electrons due to an electric field may be reduced, thus increasing durability of the selection device layer 143.

When boron and/or carbon is doped into the chalcogenide switching material, generation and growth of nuclei in the chalcogenide switching material may be reduced, thus increasing the crystallization temperature of the chalcogenide switching material. Thus, a variable resistance memory device having a 3D cross-point stack structure may be manufactured using a typical process of manufacturing memory devices. Thus, manufacturing costs may be reduced.

In some exemplary embodiments of the present inventive concept, the chalcogenide switching material may include arsenic (As) and may further include at least two of silicon (Si), germanium (Ge), antimony (Sb), tellurium (Te), selenium (Se), indium (In), or tin (Sn). Alternatively, the chalcogenide switching material may include selenium (Se) and may further include at least two of silicon (Si), germanium (Ge), antimony (Sb), tellurium (Te), arsenic (As), indium (In), or tin (Sn).

In an exemplary embodiment of the present inventive concept, the selection device layer 143 may include a chalcogenide switching material into which boron and/or carbon is doped in a content of from about 0 wt % to equal to or less than about 30 wt %. At least one of nitrogen (N), oxygen (O), phosphorus (P), or sulfur (S) may be further doped into the selection device layer 143 including the chalcogenide switching material into which boron and/or carbon is doped.

A doping concentration may be selectively controlled such that a melting point of the chalcogenide switching material into which boron and/or carbon is doped ranges from about 600° C. to about 900° C. The doping concentration may be selectively controlled such that the melting point of the chalcogenide switching material that is included in the selection device layer 143 and doped with boron and/or carbon is higher than a melting point of a chalcogenide material included in the variable resistance layer (see, e.g., the variable resistance layer 149 illustrated in FIG. 3).

Thermal stability of the selection device layer 143 will be described in more detail below. For example, when boron and/or carbon is doped into an arsenic-silicon-germanium-tellurium (As—Si—Ge—Te)-based chalcogenide switching material in a content of from about 5 wt % to about 30 wt %, a crystallization temperature of the doped As—Si—Ge—Te-based chalcogenide switching material may be at least about 50° C. higher than a crystallization temperature of the undoped As—Si—Ge—Te-based chalcogenide switching material because the generation and growth of nuclei may be inhibited.

Etching and chemical resistances of the selection device layer 143 are described below in more detail. For example, when boron and/or carbon is doped into the As—Si—Ge—Te-based chalcogenide switching material in a content of from about 5 wt % to about 30 wt %, density of the selection device layer 143 may increase. Thus, an etch rate of the doped As—Si—Ge—Te-based chalcogenide switching material may be at least about 25% lower than an etch rate of the undoped As—Si—Ge—Te-based chalcogenide switching material, and chemical damage to the doped As—Si—Ge—Te-based chalcogenide switching material may be at least about 20% lower than chemical damage to the undoped As—Si—Ge—Te-based chalcogenide switching material.

An off current passing through a variable resistance memory device will be described below in more detail. For example, when boron and/or carbon is doped into the As—Si—Ge—Te-based chalcogenide switching material in a content of from about 5 wt % to about 30 wt %, a carrier hopping site included in the As—Si—Ge—Te-based chalcogenide switching material may be reduced. Thus, resistivity of the selection device layer 143 may be at least about 25% higher than when the As—Si—Ge—Te-based chalcogenide switching material is not doped. The off current passing through the variable resistance memory device may be at least about 25% lower than when the As—Si—Ge—Te-based chalcogenide switching material is not doped.

Durability of the variable resistance memory device will be described below in more detail. For example, when boron and/or carbon is doped into the As—Si—Ge—Te-based chalcogenide switching material in a content of from about 5 wt % to about 30 wt %, density of the selection device layer 143 may increase, and thus a generation of vacancies may be inhibited and migration of atoms due to an electric field may slow. Thus, durability of the variable resistance memory device may be at least about 10 times higher than when the As—Si—Ge—Te-based chalcogenide switching material is not doped.

Degradation properties of the variable resistance memory device will be described below in more detail. For example, when boron and/or carbon is doped into the As—Si—Ge—Te-based chalcogenide switching material in a content of from about 5 wt % to about 30 wt %, density of the selection device layer 143 may increase, and thus a generation of vacancies may be inhibited and migration of atoms due to an electric field may be slowed. Thus, the degradation properties of the variable resistance memory device may be reduced more than when the As—Si—Ge—Te-based chalcogenide switching material is not doped.

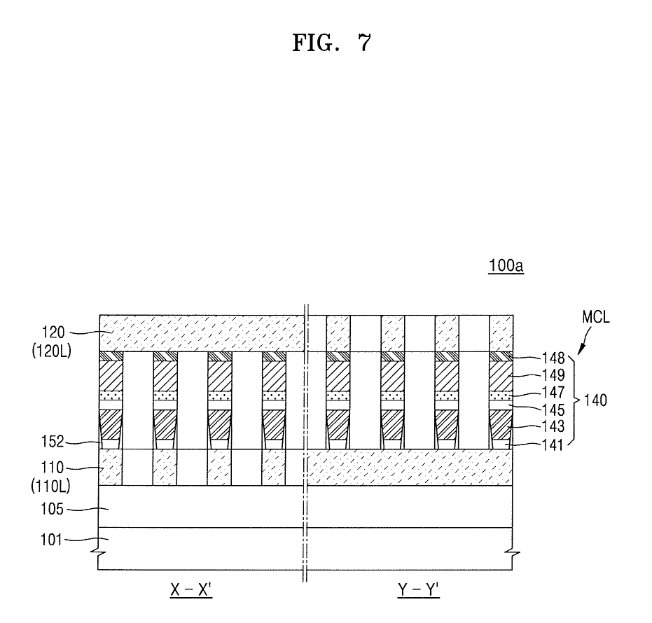

FIGS. 7 to 10 are cross-sectional views of variable resistance memory devices according to exemplary embodiments of the present inventive concept, which correspond to the cross-sectional view of FIG. 3.

FIG. 7 is a cross-sectional view of a variable resistance memory device 100a according to an exemplary embodiment of the present inventive concept. Descriptions of components that are substantially the same as those described with reference to FIGS. 2 and 3 may be omitted.

Referring to FIG. 7, the variable resistance memory device 100a according to an exemplary embodiment of the present inventive concept may differ from the variable resistance memory device 100 described with reference to FIG. 3 in that a lower electrode layer 141 and a selection device layer 143 may have damascene structures. In the variable resistance memory device 100a according to an exemplary embodiment of the present inventive concept, the lower electrode layer 141 and the selection device layer 143 may be formed by using a damascene process, while a middle electrode layer 145, a heating electrode layer 147, a variable resistance layer 149, and an upper electrode layer 148 may be formed by using an etching process. Thus, lower ends of each of the lower electrode layer 141 and the selection device layer 143 may have a relatively smaller width than upper ends of each of the lower electrode layer 141 and the selection device layer 143.

In the variable resistance memory device 100a according to an exemplary embodiment of the present inventive concept, lower spacers 152 may be formed on side surfaces of the lower electrode layer 141 and the selection device layer 143. In the variable resistance memory device 100a according to an exemplary embodiment of the present inventive concept, when the lower electrode layer 141 and the selection device layer 143 are formed by using a damascene process, the lower spacers 152 may be previously formed on a sidewall of a trench, and the lower electrode layer 141 and the selection device layer 143 may be formed. Thus, the variable resistance memory device 100a according to an exemplary embodiment of the present inventive concept may include the lower spacers 152, which may be formed on the sidewalls of the lower electrode layer 141 and the selection device layer 143. However, exemplary embodiments of the present inventive concept are not limited thereto, and the lower spacers 152 may be omitted.

In an exemplary embodiment of the present inventive concept, the selection device layer 143 may include a chalcogenide switching material into which boron and/or carbon is doped in a content of from about 0 wt % to about equal to or less than about 30 wt %.

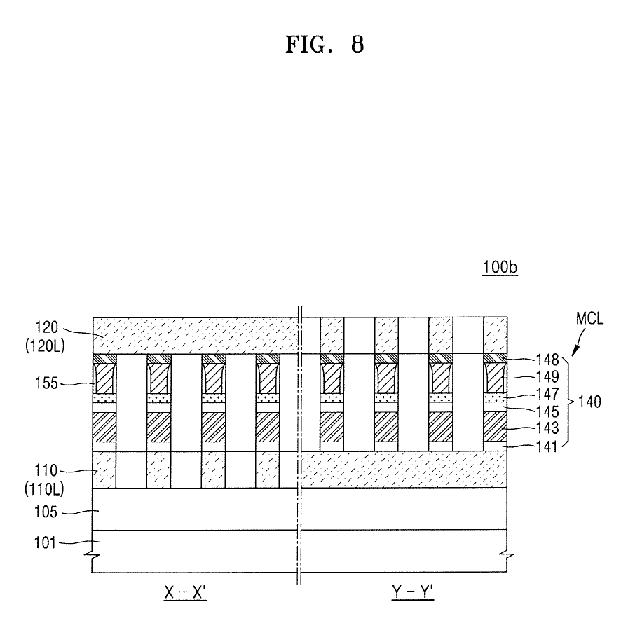

FIG. 8 is a cross-sectional view of a variable resistance memory device 100b according to an exemplary embodiment of the present inventive concept. Descriptions of components that are substantially the same as those described with reference to FIGS. 2 and 3 may be omitted.

Referring to FIG. 8, the variable resistance memory device 100b according to an exemplary embodiment of the present inventive concept may differ from the variable resistance memory device 100 described with reference to FIG. 3 in that a variable resistance layer 149 may have a damascene structure. In the variable resistance memory device 100b according to an exemplary embodiment of the present inventive concept, a lower electrode layer 141, a selection device layer 143, a middle electrode layer 145, a heating electrode layer 147, and an upper electrode layer 148 may be formed by using an etching process, while a variable resistance layer 149 may be formed by using a damascene process. In the variable resistance memory device 100b according to an exemplary embodiment of the present inventive concept, upper spacers 155 may be formed on side surfaces of the variable resistance layer 149. The upper spacers 155 may be formed by substantially the same method as the above-described method of forming the lower spacers 152 of the variable resistance memory device 100a described with reference to FIG. 7. For example, the formation of the upper spacers 155 may include forming a trench in an insulating layer, forming the upper spacers 155 on inner sidewalls of the trench, and filling the remaining space of the trench with a material included in the variable resistance layer 149. However, exemplary embodiments of the present inventive concept are not limited thereto, and the upper spacers 155 may be omitted.

In an exemplary embodiment of the present inventive concept, the selection device layer 143 may include a chalcogenide switching material into which boron and/or carbon is doped in a content of from about 0 wt % to equal to or less than about 30 wt %.

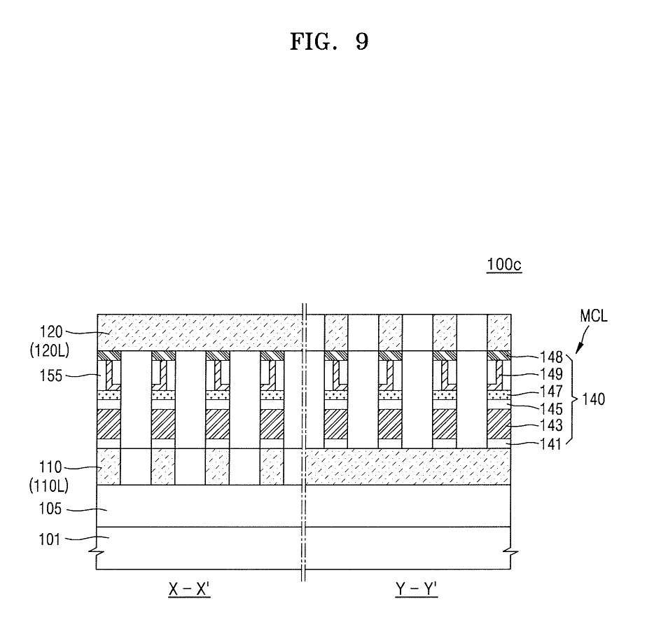

FIG. 9 is a cross-sectional view of a variable resistance memory device 100c according to an exemplary embodiment of the present inventive concept. Descriptions of components that are substantially the same as those described with reference to FIGS. 2 and 3 may be omitted.

Referring to FIG. 9, the variable resistance memory device 100c according to an exemplary embodiment of the present inventive concept may differ from the variable resistance memory device 100b described with reference to FIG. 8 except that a variable resistance layer 149 may have a damascene structure and an ‘L’-shaped structure. In the variable resistance memory device 100c according to an exemplary embodiment of the present inventive concept, a lower electrode layer 141, a selection device layer 143, a middle electrode layer 145, a heating electrode layer 147, and an upper electrode layer 148 may be formed by an etching process, and the variable resistance layer 149 may be formed by a damascene process.

In the variable resistance memory device 100c according to an exemplary embodiment of the present inventive concept, upper spacers 155 may be formed on side surfaces of the variable resistance layer 149. However, since the variable resistance layer 149 has the ‘L’-shaped structure, the upper spacers 155 may have asymmetric structures. A method of forming the variable resistance layer 149 having the ‘L’-shaped structure by using a damascene process will be described in more detail below. An insulating layer may be formed on the heating electrode layer 147, and a trench may be formed in the insulating layer. The trench may be relatively wide and may overlap memory cells 140 adjacent to the trench. A first material layer forming the variable resistance layer 149 may be formed having a relatively small thickness in the trench and on the insulating layer. A second material layer forming the upper spacers 155 may be formed on the first material layer. The resultant structure may be planarized by using a chemical mechanical polishing (CMP) process to expose a top surface of the insulating layer. After the CMP process, a mask pattern may be formed in alignment with the memory cells 140, and the first and second material layers may be etched by using the mask pattern. Thus, the variable resistance layer 149 having an ‘L’-shaped structure and the upper spacers 155 may be formed.

In an exemplary embodiment of the present inventive concept, the selection device layer 143 may include a chalcogenide switching material into which boron and/or carbon is doped in a content of from about 0 wt % to equal to or less than about 30 wt %.

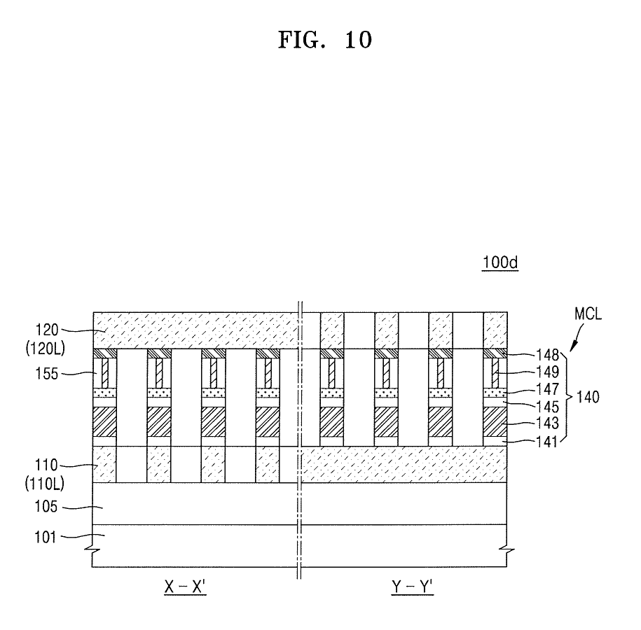

FIG. 10 is a cross-sectional view of a variable resistance memory device 100d according to an exemplary embodiment of the present inventive concept. Descriptions of components that are substantially the same as those described with reference to FIGS. 2 and 3 may be omitted.

Referring to FIG. 10, the variable resistance memory device 100d according to an exemplary embodiment of the present inventive concept may differ from the variable resistance memory device 100c described with reference to FIG. 9 in that a variable resistance layer 149 may have a dash structure. The variable resistance layer 149 having the dash structure may be formed in a similar method to a method of forming an ‘L’-shaped structure. For example, after a first material layer forming the variable resistance layer 149 is formed to a relatively small thickness in the trench and on the insulating layer, the first material layer may remain only on a sidewall of the trench by using an anisotropic etching process. A second material layer may be formed covering the remaining first material layer. The second material layer may be planarized by using a CMP process to expose a top surface of the insulating layer. A mask pattern may be formed in alignment with the memory cells 140, and the second material layer may be etched by using the mask pattern, thus forming the variable resistance layer 149 having a dash structure and upper spacers 155.

In an exemplary embodiment of the present inventive concept, the selection device layer 143 may include a chalcogenide switching material into which boron and/or carbon is doped in a content of from about 0 wt % to equal to or less than about 30 wt %.

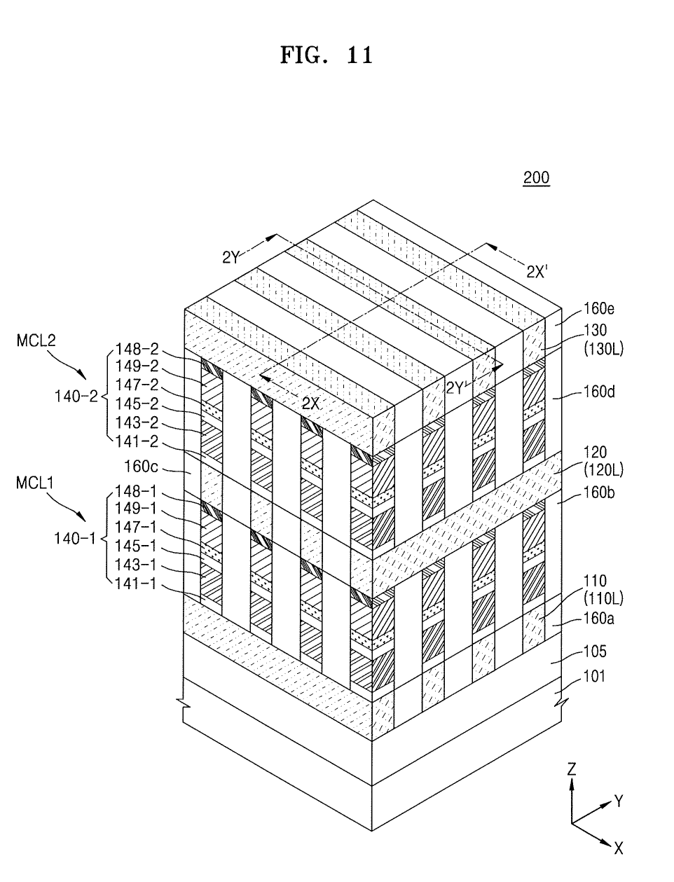

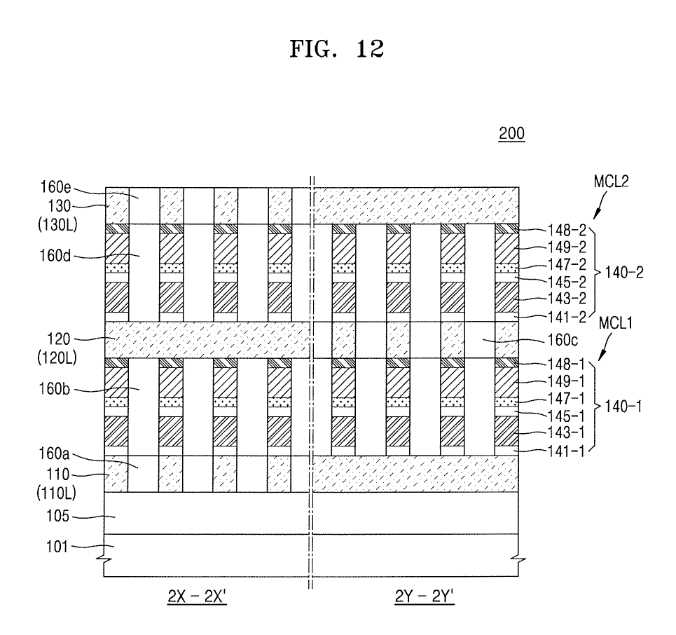

FIG. 11 is a perspective view of a variable resistance memory device according to an exemplary embodiment of the present inventive concept. FIG. 12 is a cross-sectional view taken along lines 2X-2X′ and 2Y-2Y′ of FIG. 11. Descriptions of components that are substantially the same as those described with reference to FIGS. 2 and 3 may be omitted.

Referring to FIGS. 11 and 12, a variable resistance memory device 200 may include the first electrode line layer 110L, the second electrode line layer 120L, a third electrode line layer 130L, a first memory cell layer MCL1, and a second memory cell layer MCL2, which may be positioned on the substrate 101.

An interlayer insulating layer 105 may be disposed on the substrate 101. The first electrode line layer 110L may include a plurality of first electrode lines 110, which may extend parallel to one another in a first direction (e.g., the X direction). The second electrode line layer 120L may include a plurality of second electrode lines 120, which may extend parallel to one another in a second direction (e.g., the Y direction) perpendicular to the first direction. The third electrode line layer 130L may include a plurality of third electrode lines 130, which may extend parallel to one another in the first direction (e.g., the X direction). Third electrode lines 130 may be different from the first electrode lines 110 in terms of positions in a third direction (e.g., the Z direction) but may be substantially the same as the first electrode lines 110 in terms of an extension direction or an arrangement structure. Thus, the third electrode lines 130 may be referred to as first electrode lines of the third electrode line layer 130L.

Operations of the variable resistance memory device 200 will be described in more detail below. The first electrode lines 110 and the third electrode lines 130 may be word lines, and the second electrode lines 120 may be bit lines. Alternatively, the first electrode lines 110 and the third electrode lines 130 may be bit lines, and the second electrode lines 120 may be word lines. When the first electrode lines 110 and the third electrode lines 130 correspond are word lines, the first electrode lines 110 may be lower word lines, and the third electrode lines 130 may be upper word lines. Since the second electrode lines 120 may be shared between the lower word lines and the upper word lines, the second electrode lines 120 may be a common bit line.

Each of the first electrode lines 110, the second electrode lines 120, and the third electrode lines 130 may include a metal, a conductive metal nitride, a conductive metal oxide, or a combination thereof. Each of the first electrode lines 110, the second electrode lines 120, and the third electrode lines 130 may include a metal layer and a conductive barrier layer covering at least a portion of the metal layer.

The first memory cell layer MCL1 may include a plurality of first memory cells 140-1, which are spaced apart from one another in the first direction and the second direction. The second memory cell layer MCL2 may include a plurality of second memory cells 140-2, which may be spaced apart from one another in the first direction and the second direction. The first electrode lines 110 may intersect the second electrode lines 120, and the second electrode lines 120 may intersect the third electrode lines 130. The first memory cells 140-1 may be positioned between the first electrode line layer 110L and the second electrode line layer 120L at intersections between the first electrode lines 110 and the second electrode lines 120. The second memory cells 140-2 may be positioned between the second electrode line layer 120L and the third electrode line layer 130L at intersections between the second electrode lines 120 and the third electrode lines 130.

Each of the first memory cells 140-1 may include a lower electrode layer 141-1, a selection device layer 143-1, a middle electrode layer 145-1, a heating electrode layer 147-1, a variable resistance layer 149-1, and an upper electrode layer 148-1. Each of the second memory cells 140-2 may include a lower electrode layer 141-2, a selection device layer 143-2, a middle electrode layer 145-2, a heating electrode layer 147-2, a variable resistance layer 149-2, and an upper electrode layer 148-2. The first memory cells 140-1 may have substantially the same structure as the second memory cells 140-2.

The first insulating layer 160a may be positioned between the first electrode lines 110, and the second insulating layer 160b may be positioned between the first memory cells 140-1 of the first memory cell layer MCL1. The third insulating layer 160c may be positioned between the second electrode lines 120, a fourth insulating layer 160d may be positioned between the second memory cells 140-2 of the second memory cell layer MCL2, and a fifth insulating layer 160e may be positioned between the third electrode lines 130. The first to fifth insulating layers 160a to 160e may include the same material or at least one of the first to fifth insulating layers 160a to 160e may include a different material. The first to fifth insulating layers 160a to 160e may include a dielectric material, for example, an oxide, or a nitride, and may electrically isolate devices included in each layer from one another. Air gaps may be formed instead of at least one of the second insulating layer 160b and the fourth insulating layer 160d. When the air gaps are formed, an insulating liner having a predetermined thickness may be formed between the air gaps and the first memory cells 140-1 and/or the air gaps and the second memory cells 140-2.

The variable resistance memory device 200 according to an exemplary embodiment of the present inventive concept may have a structure formed by repetitively stacking variable resistance memory devices 100. However, a structure of the variable resistance memory device 200 according to exemplary embodiments of the present inventive concept is not limited thereto. For example, the variable resistance memory device 200 according to an exemplary embodiment of the present inventive concept may have a structure in which the variable resistance memory devices 100a to 100d having various structures are stacked.

In an exemplary embodiment of the present inventive concept, each of the selection device layers 143-1 and 143-2 of the first memory cells 140-1 and the second memory cells 140-2 may include a chalcogenide switching material into which boron and/or carbon is doped in a content of from about 0 wt % to equal to or less than about 30 wt %.

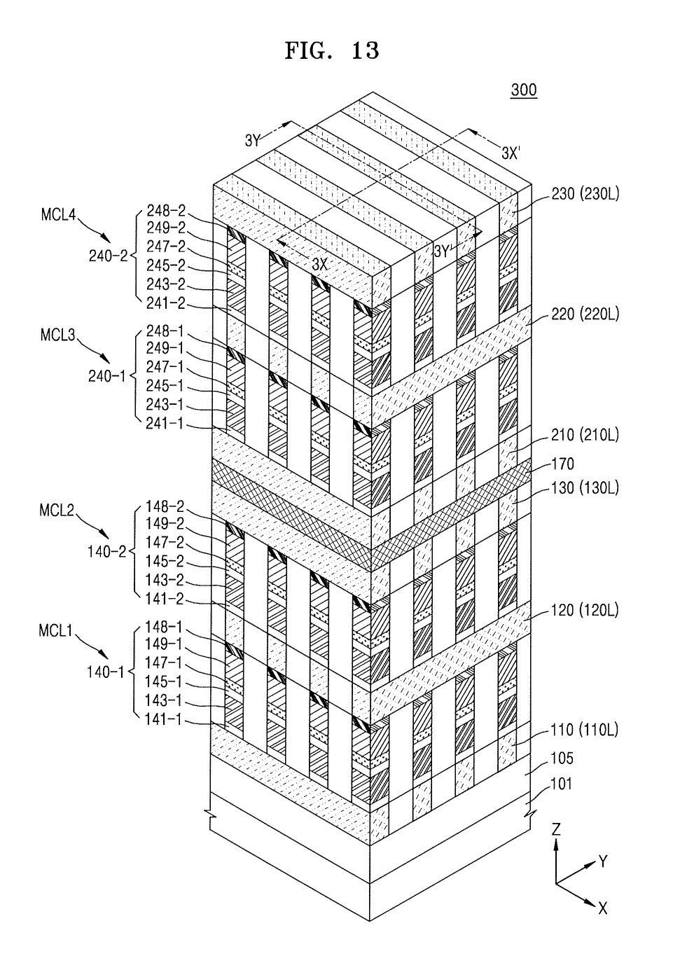

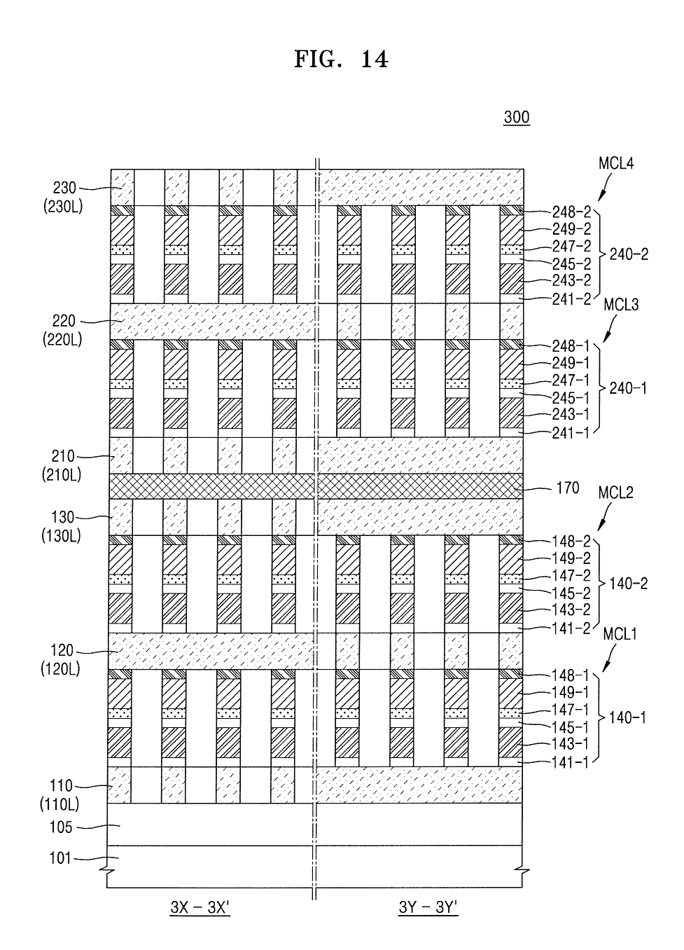

FIG. 13 is a perspective view of a variable resistance memory device according to an exemplary embodiment of the present inventive concept. FIG. 14 is a cross-sectional view taken along lines 3X-3X′ and 3Y-3Y′ of FIG. 13. Descriptions of components that are substantially the same as those described with reference to FIGS. 2 and 3 may be omitted.

Referring to FIGS. 13 and 14, a variable resistance memory device 300 according to an exemplary embodiment of the present inventive concept may have a quadruple structure including four stacked memory cell layers MCL1, MCL2, MCL3, and MCL4. For example, a first memory cell layer MCL1 may be positioned between a first electrode line layer 110L and a second electrode line layer 120L, and a second memory cell layer MCL2 may be positioned between the second electrode line layer 120L and a third electrode line layer 130L. A second interlayer insulating layer 170 may be formed on the third electrode line layer 130L. A first upper electrode line layer 210L, a second upper electrode line layer 220L, and a third upper electrode line layer 230L may be positioned on the second interlayer insulating layer 170. The first upper electrode line layer 210L may include first upper electrode lines 210 having substantially the same structures as first electrode lines 110. The second upper electrode line layer 220L may include second upper electrode lines 220 having substantially the same structures as second electrode lines 120. The third upper electrode line layer 230L may include third upper electrode lines 230 having substantially the same structures as the third electrode lines 130 or the first electrode lines 110. The first upper memory cell layer MCL3 may be positioned between the first upper electrode line layer 210L and the second upper electrode line layer 220L. The second upper memory cell layer MCL4 may be positioned between the second upper electrode line layer 220L and the third upper electrode line layer 230L.

The first to third electrode line layers 110L to 130L and the first and second memory cell layers MCL1 and MCL2 may be substantially the same as the first to third electrode line layers 110L to 130L and the first and second memory cell layers MCL1 and MCL2 described with reference to FIGS. 2, 3, 11, and 12. The first to third upper electrode line layers 210L to 230L and the first and second upper memory cell layers MCL3 and MCL4 may be substantially the same as the first to third electrode line layers 110L to 130L and the first and second memory cell layers MCL1 and MCL2 except that the first to third upper electrode line layers 210L to 230L and the first and second upper memory cell layers MCL3 and MCL4 may be positioned on the second interlayer insulating layer 170 instead of a first interlayer insulating layer 105.

In an exemplary embodiment of the present inventive concept, each of the selection device layers 143-1, 143-2, 243-1, and 243-2 included in the first memory cells 140-1, the second memory cells 140-2, the first upper memory cells 240-1, and the second upper memory cells 240-2 may include a chalcogenide switching material into which boron and/or carbon is doped in a content of from about 0 wt % to equal to or less than about 30 wt %.

The variable resistance memory device 300 according to an exemplary embodiment of the present inventive concept may have a structure formed by repetitively stacking variable resistance memory devices 100. However, a structure of the variable resistance memory device 300 according to exemplary embodiments of the present inventive concept is not limited thereto. For example, the variable resistance memory device 300 according to an exemplary embodiment of the present inventive concept may have a structure formed by stacking variable resistance memory devices 100a to 100d having various structures.

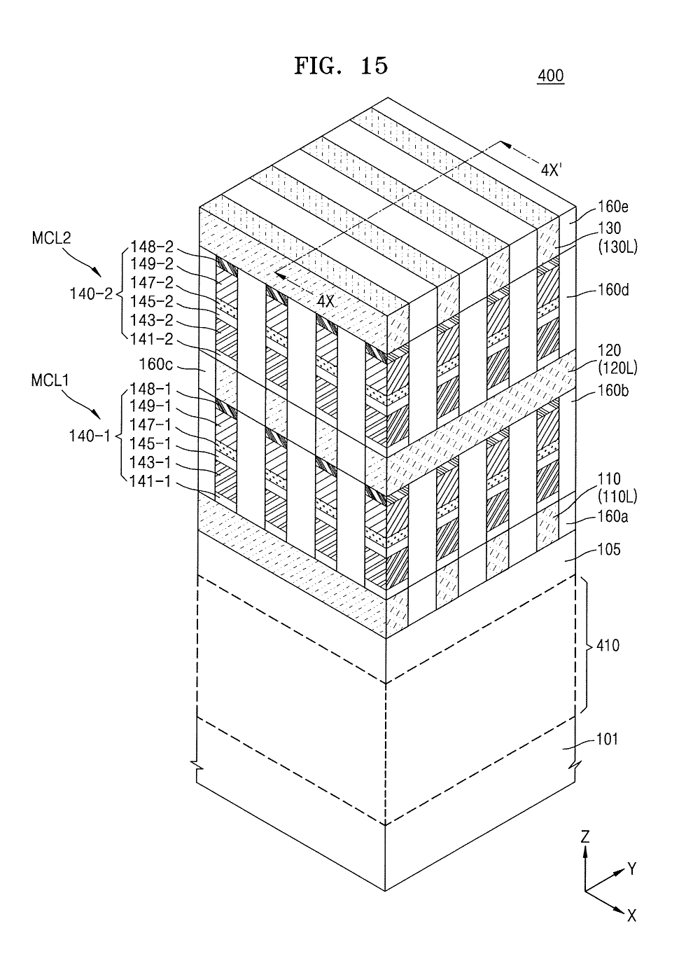

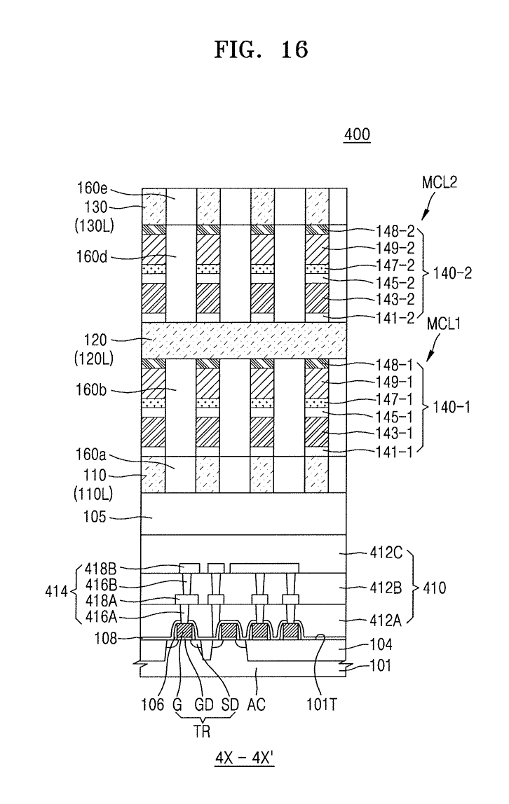

FIG. 15 is a perspective view of a variable resistance memory device according to an exemplary embodiment of the present inventive concept. FIG. 16 is a cross-sectional view taken along a line 4X-4X′ of FIG. 15. Descriptions of components that are substantially the same as those described with reference to FIGS. 2 and 3 may be omitted.

Referring to FIGS. 15 and 16, a variable resistance memory device 400 may include a driver circuit region 410 formed at a first level on a substrate 101 and a first memory cell layer MCL1 and a second memory cell layer MCL2 formed at a second level on the substrate 101.

A term “level” may refer to a height in a vertical direction (e.g., with respect to the Z illustrated in FIGS. 15 and 16) from the substrate 101. The first level may be closer to the substrate 101 than the second level on the substrate 101.

The driver circuit region 410 may be a region in which peripheral circuits or driver circuits for driving memory cells included in the first memory cell layer MCL1 and the second memory cell layer MCL2 are positioned. For example, the peripheral circuits positioned in the driver circuit region 410 may be circuits capable of processing data input to and output from the first memory cell layer MCL1 and the second memory cell layer MCL2 at relatively high speed. For example, the peripheral circuits may be a page buffer, a latch circuit, a cache circuit, a column decoder, a sense amplifier, a data in/out circuit, or a row decoder.

An active region AC for a driver circuit may be defined by a device isolation layer 104 in the substrate 101. A plurality of transistors TR included in the driver circuit region 410 may be formed on the active region AC of the substrate 101. Each of the plurality of transistors TR may include a gate G, a gate insulating layer GD, and source and drain regions SD. Both sidewalls of the gate G may be covered with insulating spacers 106, and an etch stop layer 108 may be formed on the gate G and the insulating spacers 106. The etch stop layer 108 may include an insulating material, such as silicon nitride or silicon oxynitride.

A plurality of interlayer insulating layers 412A, 412B, and 412C may be sequentially stacked on the etch stop layer 108. The plurality of interlayer insulating layers 412A, 412B, and 412C may include silicon oxide, silicon oxynitride, or silicon oxynitride.

A driver circuit region 410 may include multi-layered interconnection structures 414, which may be electrically connected to a plurality of transistors TR. The multi-layered interconnection structures 414 may be electrically insulated from one another by the plurality of interlayer insulating layers 412A, 412B, and 412C.

Each of the multi-layered interconnection structures 414 may include a first contact 416A, a first interconnection layer 418A, a second contact 416B, and a second interconnection layer 418B, which are sequentially stacked on the substrate 101 and electrically connected to one another. In some exemplary embodiments of the present inventive concept, the first interconnection layer 418A and the second interconnection layer 418B may include a metal, a conductive metal nitride, a metal silicide, or a combination thereof. For example, the first interconnection layer 418A and the second interconnection layer 418B may include a conductive material, such as tungsten, molybdenum, titanium, cobalt, tantalum, nickel, tungsten silicide, titanium silicide, cobalt silicide, tantalum silicide, or nickel silicide.

FIG. 16 illustrates an example in which each of the multi-layered interconnection structures 414 is a double interconnection structure including the first interconnection layer 418A and the second interconnection layer 418B, but exemplary embodiments of the present inventive concept are not limited thereto. For example, each of the multi-layered interconnection structures 414 may include at least three layers according to a layout of the driver circuit region 410 and a kind and arrangement of gates G.

An interlayer insulating layer 105 may be formed on the plurality of interlayer insulating layers 412A, 412B, and 412C. The first memory cell layer MCL1 and the second memory cell layer MCL2 may be positioned on the interlayer insulating layer 105.

An interconnection structure may be connected between the first memory cell layer MCL1 and the second memory cell layer MCL2 and may penetrate the interlayer insulating layer 105.

In the variable resistance memory device 400 according to an exemplary embodiment of the present inventive concept, the first memory cell layer MCL1 and the second memory cell layer MCL2 may be positioned on the driver circuit region 410, thus increasing a density of the variable resistance memory device 400.

In an exemplary embodiment of the present inventive concept, each of the selection device layers 143-1 and 143-2 of the first memory cells 140-1 and the second memory cells 140-2 may include a chalcogenide switching material into which boron and/or carbon is doped in a content of from about 0 wt % to equal to or less than about 30 wt %.

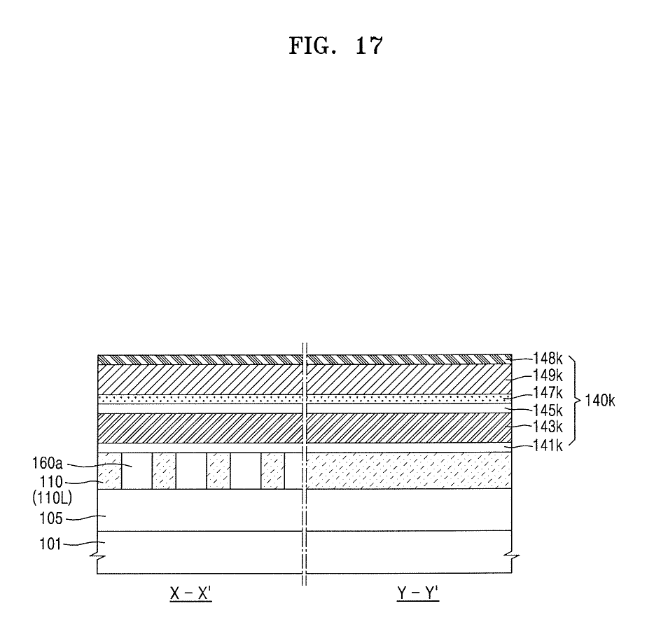

FIGS. 17 to 19 are cross-sectional views, illustrating a method of manufacturing the variable resistance memory device of FIG. 2, according to an exemplary embodiment of the present inventive concept.

Referring to FIG. 17, the interlayer insulating layer 105 may be formed on the substrate 101. The interlayer insulating layer 105 may include, for example, silicon oxide or silicon nitride. However, exemplary embodiments of the present inventive concept are not limited thereto, and a material included in the interlayer insulating layer 105 is not limited to the above-described materials. The first electrode line layer 110L may be formed on the interlayer insulating layer 105. The first electrode line layer 110L may include a plurality of first electrode lines 110, which may extend in a first direction (e.g., the X direction) and may be spaced apart from each other. The first electrode lines 110 may be formed by an etching process or a damascene process. A material included in the first electrode lines 110 may be the same as described with reference to FIGS. 2 and 3. The first insulating layer 160a may be positioned between the first electrode lines 110 and extend in the first direction.

A lower electrode material layer 141k, a selection device material layer 143k, a middle electrode material layer 145k, a heating electrode material layer 147k, a variable resistor material layer 149k, and an upper electrode material layer 148k may be sequentially stacked on the first electrode line layer 110L and the first insulating layer 160a and may form a stack structure 140k. A material or function of each material layer included in the stack structure 140k may be substantially the same as described with reference to FIGS. 2 and 3.

The selection device material layer 143k may be formed by using a target including at least one of boron and carbon and a chalcogenide switching material by a physical vapor deposition (PVD) process. Alternatively, the selection device material layer 143k may be formed by using a source including at least one of boron and carbon and a chalcogenide switching material by a chemical vapor deposition (CVD) process or an atomic layer deposition (ALD) process.

In an exemplary embodiment of the present inventive concept, the selection device material layer 143k may include a chalcogenide switching material into which boron and/or carbon is doped in a content of from about 0 wt % to equal to or less than about 30 wt %. A desired dopant concentration may be obtained by controlling the content of boron and/or carbon included in the target or the source.

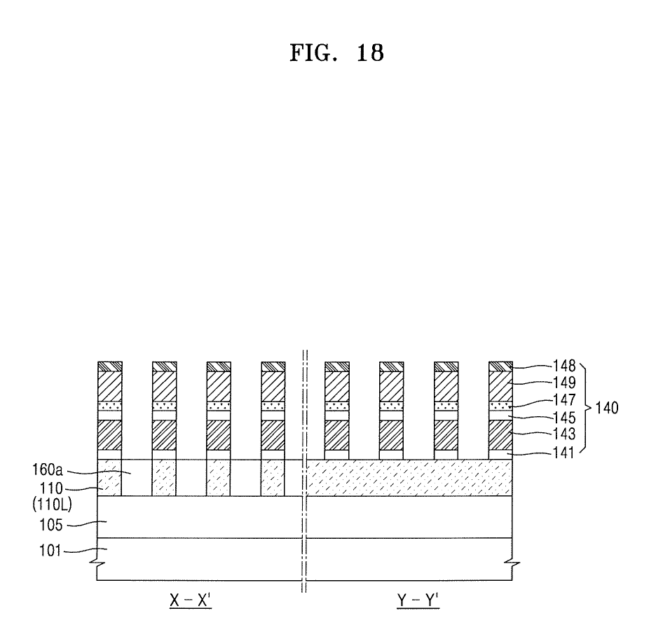

Referring to FIG. 18, after a stack structure (e.g., the stack structure 140k illustrated in FIG. 17) is formed, mask patterns may be formed on the stack structure 140k and may be spaced apart from each other in a first direction (e.g., the X direction) and a second direction (e.g., the Y direction). Thus, the stack structure 140K may be etched by using the mask patterns to expose portions of top surfaces of the first insulating layer 160a and the first electrode lines 110, thus forming a plurality of memory cells 140.

The memory cells 140 may be spaced apart from each other in the first direction and the second direction based on structures of the mask patterns, and may be electrically connected to the first electrode lines 110 disposed under the memory cells 140. Each of the memory cells 140 may include the lower electrode layer 141, the selection device layer 143, the middle electrode layer 145, the heating electrode layer 147, the variable resistance layer 149, and the upper electrode layer 148. After the memory cells 140 are formed, the remaining mask patterns may be removed by an ashing process and a strip process.

A method of forming the memory cells 140 may include an etching process. However, exemplary embodiments of the present inventive concept are not limited thereto, and the method of forming the memory cells 140 is not limited to the etching process. In an exemplary embodiment of the present inventive concept, the memory cells 140 may be formed by a damascene process. For example, the formation of the variable resistance layers 149 of the memory cells 140 may include forming an insulating material layer and etching the insulating material layer to form a trench exposing a top surface of the heating electrode layer 147. The trench may be filled with a phase-change material, and the phase-change material may be planarized by using a CMP process, thus forming the variable resistance layer 149.

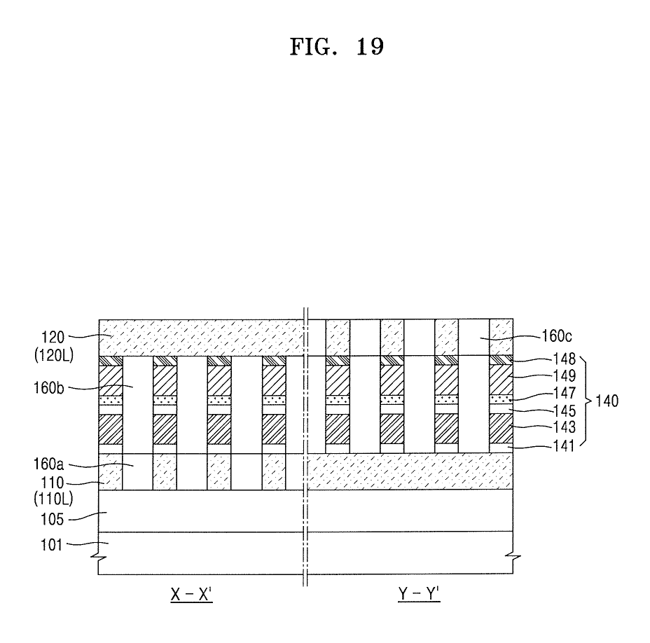

Referring to FIG. 19, the second insulating layer 160b may be formed to fill spaces between the memory cells 140. The second insulating layer 160b may include an oxide or a nitride, which may be the same as or different from the first insulating layer 160a. An insulating material layer may be formed to a sufficient thickness to completely fill the spaces between the memory cells 140, and planarized by a CMP process until a top surface of the upper electrode layer 148 is exposed. Thus, the second insulating layer 160b may be formed.

A conductive layer for a second electrode line layer may be formed and patterned by an etching process to form second electrode lines 120. The second electrode lines 120 may extend in the second direction (e.g., the Y direction) and may be spaced apart from each other. The third insulating layer 160c may be positioned between the second electrode lines 120 and may extend in the second direction. A method of forming the second electrode lines 120 may include an etching process. However, exemplary embodiments of the present inventive concept are not limited thereto, and the method of forming the second electrode lines 120 is not limited to the etching process. For example, the second electrode lines 120 may be formed by a damascene process. The formation of the second electrode lines 120 by a damascene process may include forming an insulating material layer on the memory cells 140 and the second insulating layer 160b, etching the insulating material layer to form trenches extending in the second direction and exposing a top surface of the variable resistance layer 149, filling the trenches with a conductive material, and planarizing the conductive material. The formation of the second electrode lines 120 may include forming an insulating material layer to fill spaces between the memory cells 140, planarizing the insulating material layer, and forming trenches in the insulating material layer. The second insulating layer 160b and the third insulating layer 160c may be formed as a one-body type by using the same material.

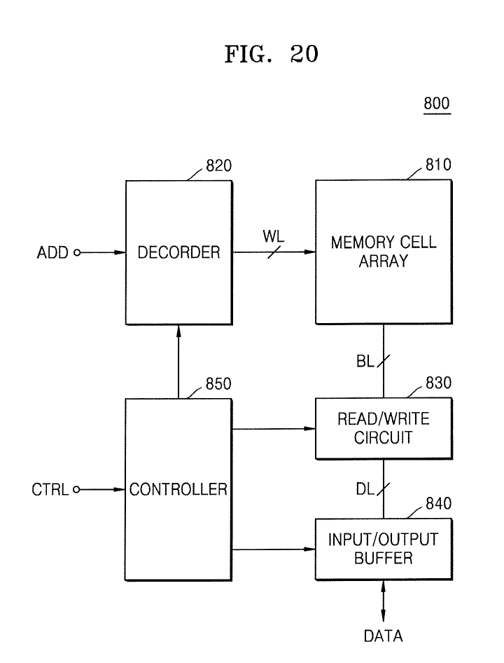

FIG. 20 is a block diagram of a memory device according to an exemplary embodiment of the present inventive concept.

Referring to FIG. 20, a memory device 800 may include a memory cell array 810, a decoder 820, a read/write circuit 830, an I/O buffer 840, and a controller 850. The memory cell array 810 may include at least one variable resistance memory device, such as the variable resistance memory device 100, the variable resistance memory devices 100a to 100d, the variable resistance memory device 200, the variable resistance memory device 300, or the variable resistance memory device 400.

A plurality of memory cells included in the memory cell array 810 may be connected the decoder 820 through word lines WL and may be connected to the read/write circuit 830 through bit lines BL. The decoder 820 may receive an external address ADD and decode a row address and a column address to be accessed in the memory cell array 810 under the control of the controller 850 that operates in response to a control signal CTRL.

The read/write circuit 830 may receive data DATA from the I/O buffer 840 and a data line DL and write data to a selected memory cell of the memory cell array 810 under the control of the controller 850 or may provide data read from a selected memory cell of the memory cell array 810 to the I/O buffer 840 under the control of the controller 850.

While the present inventive concept has been particularly shown and described with reference to exemplary embodiments thereof, it will be understood that various changes in form and details may be made therein without departing from the spirit and scope of the present inventive concept.

1. A variable resistance memory device comprising:
a first electrode layer;
a selection device layer on the first electrode layer, the selection device layer including a first chalcogenide material obtained by doping at least one of boron (B) or carbon (C) into a chalcogenide switching material;
a second electrode layer on the selection device layer;
a variable resistance layer on the second electrode layer, the variable resistance layer including a second chalcogenide material including at least one different element from the chalcogenide switching material; and
a third electrode layer on the variable resistance layer.

2. The device of claim 1, wherein a content of boron in the first chalcogenide material is from greater than 0 wt % to equal to or less than about 30 wt %.

3. The device of claim 1, wherein a content of carbon in the first chalcogenide material is from greater than 0 wt % to equal to or less than about 30 wt %.

4. The device of claim 1, wherein a sum of a content of boron in the first chalcogenide material and a content of carbon in the first chalcogenide is from greater than 0 wt % to equal to or less than about 30 wt %.

5. The device of claim 1, wherein the selection device layer comprises the first chalcogenide material into which at least one of nitrogen (N), oxygen (O), phosphorus (P), or sulfur (S) is further doped.

6. The device of claim 1, wherein the chalcogenide switching material comprises arsenic (As) and at least two of silicon (Si), germanium (Ge), antimony (Sb), tellurium (Te), selenium (Se), indium (In), or tin (Sn).

7. The device of claim 1, wherein the chalcogenide switching material comprises selenium (Se) and further comprises at least two selected from silicon (Si), germanium (Ge), antimony (Sb), tellurium (Te), arsenic (As), indium (In), or tin (Sn).

8. The device of claim 1, wherein a melting point of the first chalcogenide material is from about 600° C. to about 900° C.

9. The device of claim 1, wherein the variable resistance layer comprises the second chalcogenide material, and wherein the second chalcogenide material is doped with at least one of boron (B), carbon (C), nitrogen (N), oxygen (O), phosphorus (P), or sulfur (S).

10. The device of claim 1, wherein the second chalcogenide material comprises at least two of silicon (Si), germanium (Ge), antimony (Sb), tellurium (Te), bismuth (Bi), indium (In), tin (Sn), or selenium (Se).

11. The device of claim 1, wherein a melting point of the second chalcogenide material is from about 500° C. to about 800° C.

12. The device of claim 1, wherein a melting point of the first chalcogenide material is higher than a melting point of the second chalcogenide material.

13. The device of claim 1, wherein each of the first electrode layer, the second electrode layer, and the third electrode layer comprises at least one of carbon (C), titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tungsten (W), or tungsten nitride (WN).

14. The device of claim 1, wherein the second electrode layer comprises a heating electrode layer in contact with the variable resistance layer,
and wherein the heating electrode layer comprises a carbon-based conductive material.

15. A variable resistance memory device comprising:
a first electrode line layer extending in a first direction, the first electrode line layer including a plurality of first electrode lines spaced apart from one another;
a second electrode line layer above the first electrode line layer, the second electrode line layer extending in a second direction different from the first direction and including a plurality of second electrode lines spaced apart from one another;
a third electrode line layer above the second electrode line layer, the third electrode line layer including a plurality of third electrode lines;
a first memory cell layer between the first electrode line layer and the second electrode line layer, the first memory cell layer including a plurality of first memory cells arranged at intersections between the first electrode lines and the second electrode lines; and
a second memory cell layer between the second electrode line layer and the third electrode line layer, the second memory cell layer including a plurality of second memory cells arranged at intersections between the third electrode lines and the second electrode lines,
wherein each of the plurality of first memory cells and each of the plurality of second memory cells comprises a selection device layer, an electrode layer, and a variable resistance layer,
wherein the selection device layer comprises a first chalcogenide material obtained by doping at least one of boron (B) or carbon (C) into a chalcogenide switching material, and
wherein the variable resistance layer comprises a second chalcogenide material having at least one element different from an element included in the chalcogenide switching material.

16. The device of claim 15, wherein a content of boron in the first chalcogenide material is from greater than 0 wt % to equal to or less than about 30 wt %.

17. The device of claim 15, wherein a content of carbon in the first chalcogenide material is from greater than 0 wt % to equal to or less than about 30 wt %.

18. The device of claim 15, wherein a sum of a content of boron in the first chalcogenide material and a content of carbon in the first chalcogenide material is from greater than 0 wt % to equal to or less than about 30 wt %.

19. The device of claim 15, wherein a melting point of the first chalcogenide material is from about 600° C. to about 900° C.

20-21. (canceled)

22. The device of claim 15, further comprising a driver circuit region under the first electrode line layer, the driver circuit region including peripheral circuits or driver circuits configured to drive the plurality of memory cells.

23-34. (canceled)
